(19) United States
(12) Patent Application Publication
(10) Pub. No.: US 2014/0210061 A1
(43) Pub. Date: Jul. 31, 2014

(54) CHIP ARRANGEMENT AND CHIP PACKAGE

(71) Applicant: INFINEON TECHNOLOGIES AUSTRIA AG, Villach (AT)

(72) Inventors: Ralf Otremba, Kaufbeuren (DE); Klaus Schiess, Allensbach (DE); Wolfgang Scholz, Olching (DE); Teck Sim Lee, Melaka (MY); Fabio Brucchi, Villach (AT); Davide Chiola, Villach (AT); Wolfgang Peinhopf, Viktring (AT); Franz Stueckler, St. Stefan (AT)

(73) Assignee: INFINEON TECHNOLOGIES AUSTRIA AG, Villach (AT)

(21) Appl. No.: 13/751,207

(22) Filed: Jan. 28, 2013

(51) Int. Cl. H01L 23/495

(52) U.S. Cl. CPC H01L 23/49575
USPC 257/676

(57) ABSTRACT

Various embodiments provide a chip arrangement. The chip arrangement may include a first chip including a first contact and a second contact; a second chip; a leadframe including a first leadframe portion and a second leadframe portion electrically insulated from the first leadframe portion; and a plurality of pins coupled to the leadframe. At least one first pin is coupled to the first leadframe portion and at least one second pin is coupled to the second leadframe portion. The first contact of the first chip is electrically coupled to the first leadframe portion and the second contact of the first chip is coupled to the second leadframe portion. A contact of the second chip is electrically coupled to the second leadframe portion.

### TECHNICAL FIELD

Various embodiments relate generally to a chip arrangement and a chip package. By way of example, various embodiments relate to a multi-chip through-hole-package.

### BACKGROUND

Power semiconductor chips may be integrated into an electronic package, e.g. a through-hole-package (THP) or a surface-mounted-device (SMD).

Currently, discrete through-hole-packages, e.g., TO218, TO220, TO247, TO251, are used for discrete power semiconductor chips in power applications, e.g. mainly for high-voltage applications of larger than 200V. However, discrete packages require much board space and more assembly costs for electrical and/or thermal redistribution, e.g. in a standard half-bridge circuitry.

It is desired to provide multi-chip packages for power applications.

### SUMMARY

Various embodiments provide a chip arrangement. The chip arrangement may include a first chip including a first contact and a second contact; a second chip; a leadframe including a first leadframe portion and a second leadframe portion electrically insulated from the first leadframe portion; and a plurality of pins coupled to the leadframe. At least one first pin is coupled to the first leadframe portion and at least one second pin is coupled to the second leadframe portion. The first contact of the first chip is electrically coupled to the first leadframe portion and the second contact of the first chip is coupled to the second leadframe portion. A contact of the second chip is electrically coupled to the second leadframe portion.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a diagram illustrating a chip arrangement according to an embodiment;

FIG. 2 shows a circuit corresponding to the chip arrangement of FIG. 1;

FIG. 3 shows an image illustrating the chip arrangement of FIG. 1;

FIG. 4 shows a leadframe according to an embodiment;

FIG. 5 shows a leadframe according to an embodiment;

FIG. 6 shows a diagram illustrating a chip arrangement according to another embodiment;

FIG. 7 shows a diagram illustrating a chip arrangement according to a further embodiment;

FIG. 8 shows a chip package corresponding to the chip arrangement of FIG. 7.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

The word “coupled” is used herein to indicate that two elements co-operate or interact with each other regardless whether they are in direct or indirect contact (e.g. physical or electrical contact).

Various embodiments are directed to a chip arrangement. The chip arrangement may include a first chip including a first contact and a second contact; a second chip; a leadframe including a first leadframe portion and a second leadframe portion electrically insulated from the first leadframe portion; and a plurality of pins coupled to the leadframe. At least one first pin is coupled to the first leadframe portion and at least one second pin is coupled to the second leadframe portion. The first contact of the first chip is electrically coupled to the first leadframe portion and the second contact of the first chip is coupled to the second leadframe portion. A contact of the second chip is electrically coupled to the second leadframe portion.

At least one of the first chip and the second chip may include a power semiconductor chip, such as a power MOSFET (Metal Oxide Semiconductor Field Effect Transistor), a JFET (Junction Gate Field Effect Transistor), an IGBT (Insulated Gate Bipolar Transistor), or a power bipolar transistor.

In an embodiment, the first chip may include a field effect transistor power semiconductor chip, e.g. a power MOSFET or a JFET. The second contact of the first chip may be a source contact/terminal of the field effect transistor power semiconductor chip. The first contact of the first chip may be a drain contact/terminal of the field effect transistor power semiconductor chip.

In various embodiments, the first chip may include a bipolar transistor power semiconductor chip. The second contact of the first chip may be an emitter contact/terminal of the bipolar transistor power semiconductor chip. The first contact of the first chip may be a collector contact/terminal of the bipolar transistor power semiconductor chip.

In yet a further embodiment, the first chip may include an IGBT power semiconductor chip. The second contact of the first chip may be an emitter contact/terminal of the IGBT power semiconductor chip. The first contact of the first chip may be a collector contact/terminal of the IGBT power semiconductor chip.

In various embodiments, at least one of the first chip and the second chip may have a chip size in the range from about 1 mm² to about 800 mm², e.g., in the range from about 10 mm² to about 50 mm².

According to various embodiments, at least one leadframe portion of the plurality of leadframe portions has a length in the range from about 1 mm to about 4 cm, e.g., in the range from about 1 mm to about 2 cm in an exemplary embodiment. At least one leadframe portion of the plurality of leadframe portions may have a width in the range from about 1 mm to about 2 cm, e.g. in the range from about 1 mm to about 1 cm in an exemplary embodiment.

In one embodiment, at least one pin (which may also be referred to as lead) of the plurality of pins (which may also be referred to as leads) has a length in the range from about 1 mm to about 4 cm, e.g., in the range from about 1 mm to about 2 cm in an exemplary embodiment. In various embodiments, at least one pin of the plurality of pins has a length in the range from about 0.5 cm to about 5 cm, e.g., in the range from about 1 cm to about 3 cm in an exemplary embodiment.

In an embodiment, at least one pin of the plurality of pins has a width in the range from about 0.5 mm to about 5 mm, e.g. in the range from about 1 mm to about 3 mm in an exemplary embodiment.

According to various embodiments, at least one pin of the plurality of pins has a first length and at least one other pin of the plurality of pins has a second length, wherein the second length is smaller than the first length. In various embodiments, the at least one pin having the first length may be directly connected with the leadframe, e.g. formed as a part of the leadframe; and the at least one other pin having the second length may be indirectly connected with the leadframe, e.g. formed separately from the leadframe.

In various embodiments, the leadframe portions may be free from encapsulation material. In various embodiments, the leadframe portions may be partially free from encapsulation material.

The leadframe portions may be made of a metal or a metal alloy, e.g. including a material selected from a group consisting of: copper (Cu), iron nickel (FeNi), steel, and the like.

According to various embodiments, at least one pin of the plurality of pins may be bent into a first direction, and at least one other pin of the plurality of pins is bent into a second direction different from the first direction. In various embodiments, the second direction faces away from the first direction. In various embodiments, the at least one pin of the plurality of pins bent into the first direction may be a control pin; and the at least one other pin of the plurality of pins bent into the second direction may be a power pin.

Another embodiment may be directed to a chip package. The chip package may include a chip arrangement and encapsulation material encapsulating the chip arrangement. The chip arrangement may include a first chip including a first contact and a second contact; a second chip; a leadframe including a first leadframe portion and a second leadframe portion electrically insulated from the first leadframe portion; and a plurality of pins coupled to the leadframe. At least one first pin is coupled to the first leadframe portion and at least one second pin is coupled to the second leadframe portion. the first contact of the first chip is electrically coupled to the first leadframe portion and the second contact of the first chip is coupled to the second leadframe portion; and a contact of the second chip is electrically coupled to the second leadframe portion. At least a portion of the first pin and at least a portion of the second pin is free of the encapsulation material.

Various embodiments described with regard to the chip arrangement above are analogously valid for the chip package including a chip arrangement.

The chip package may be configured as a through hole package.

In various embodiments, the first chip may include a field effect transistor power semiconductor chip, e.g. a power MOSFET or a JFET. The second contact of the first chip may be a source contact/terminal of the field effect transistor power semiconductor chip. The first contact of the first chip may be a drain contact/terminal of the field effect transistor power semiconductor chip.

In various embodiments, the first chip may include a bipolar transistor power semiconductor chip. The second contact of the first chip may be an emitter contact/terminal of the bipolar transistor power semiconductor chip. The first contact of the first chip may be a collector contact/terminal of the bipolar transistor power semiconductor chip.

In various embodiments, the first chip may include an IGBT power semiconductor chip. The second contact of the first chip may be an emitter contact/terminal of the IGBT power semiconductor chip. The first contact of the first chip may be a collector contact/terminal of the IGBT power semiconductor chip.

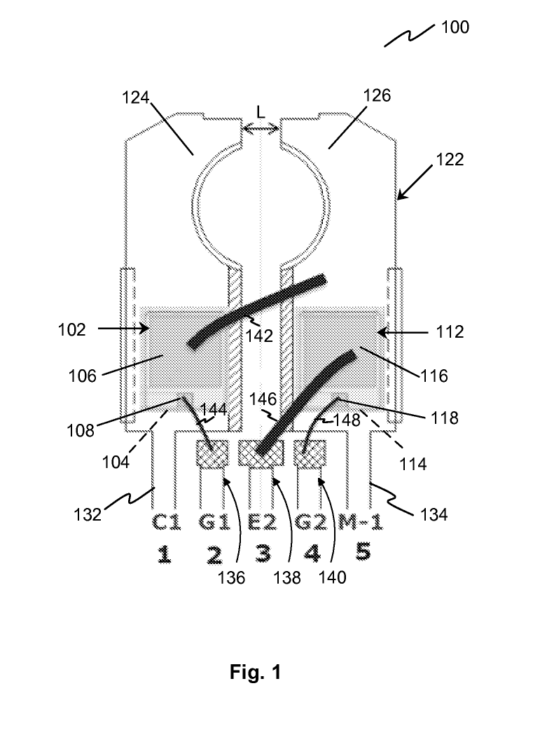

FIG. 1 shows a diagram illustrating a chip arrangement 100 according to various embodiments.

As shown in FIG. 1, the chip arrangement 100 may include a first chip 102, a second chip 112, and a leadframe 122 on which the first chip 102 and the second chip 112 may be mounted. The leadframe 122 may include a first leadframe portion 124 and a second leadframe portion 126 electrically insulated from the first leadframe portion 124. In various embodiments, the first chip 102 may be mounted on the first leadframe portion 124, and the second chip 112 may be mounted on the second leadframe portion 126.

The first chip 102 may include a first contact 104 and a second contact 106. The first contact 104 may be positioned at the backside of the first chip 102, and is electrically coupled to the first leadframe portion 124. The second contact 106 of the first chip 102 is electrically coupled to the second leadframe portion 126, e.g. via a bond wire 142 connected between the second contact 106 and the second leadframe portion 126.

The second chip 112 may include a contact 114 electrically coupled to the second leadframe portion 126. The contact 114 may be positioned at the backside of the second chip 112.

The chip arrangement 100 may further include a plurality of pins 132, 134, 136, 138, 140 (which may also be referred to as leads) coupled to the leadframe 122. In various embodiments, at least one first pin 132 is coupled to the first leadframe portion 124, and at least one second pin 134 is coupled to the second leadframe portion 126. In various embodiments, as shown in FIG. 1, the first pin 132 and the second pin 134 may be formed as parts of the leadframe 122, for example, as pins extending from the first leadframe portion 124 and the second leadframe portion 126. In other embodiments (not shown), the first pin 132 coupled to the first leadframe portion 124 and the second pin 134 coupled to the second leadframe portion 126 may also be formed to be separate from the leadframe portions 124, 126, and the electrical coupling therebetween may be formed via bonding wires, for example.

In various embodiments, as shown in FIG. 1, other pins 136, 138, 140 may be provided which may be formed separately from the leadframe 122. These pins 136, 138, 140 may be configured to be electrically connected with the first chip 102 and the second chip 112, via bonding wires, for example. The first and second pins 132, 134 may have a first length, and the other pins 136, 138, 140 may have a second length smaller than the first length, as shown in the embodiment of FIG. 1.

At least one of the first chip 102 and the second chip 112 may include a power semiconductor chip, such as a power MOSFET (Metal Oxide Semiconductor Field Effect Transistor), a JFET (Junction Gate Field Effect Transistor), an IGBT (Insulated Gate Bipolar Transistor), or a power bipolar transistor, and the like.

In various embodiments, the first chip 102 and the second chip 112 may be IGBT power semiconductor chips.

The first contact 104 of the first chip 102 may be a collector terminal (as an example of a power terminal) of the IGBT power semiconductor chip, which may be (electrically conductively) coupled to the first leadframe portion 124 and to the first pin 132. The first pin 132 is depicted as C1, which is connected to the collector terminal 104 of the first chip 102. The second contact 106 connected to the second leadframe portion 126 may be the emitter terminal of the first chip 102. The first chip 102 may further include a third contact 108, which may be the gate terminal, connected to the pin 136 (depicted as G1) via a bond wire 144.

The contact 114 of the second chip 112 may be a collector terminal of the IGBT power semiconductor chip 112. The collector contact 114 may be coupled to the second leadframe portion 126 and is further coupled to the second pin 134 (depicted as M-1). The emitter terminal 106 (as another example of a power terminal) of the first chip 102 is also coupled to the second pin 134 through the bond wire 142 and the second leadframe portion 126. The second chip 112 may include an emitter terminal 116 coupled to the pin 138 through a bond wire 146, and the pin 138 is depicted as E2. Further, a gate terminal 118 of the second chip 112 may be connected to the pin 140 (depicted as G2) via a bond wire 148.

In various embodiments, at least one of the first chip 102 and the second chip 112 may have a chip size in the range from about 1 mm² to about 800 mm², e.g., in the range from about 10 mm² to about 50 mm² in an exemplary embodiment.

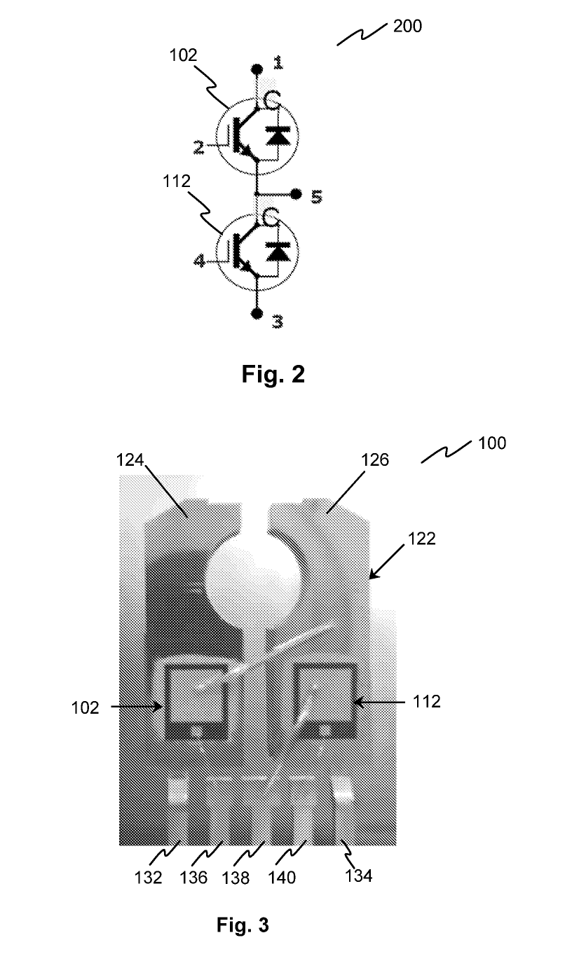

A circuit 200 corresponding to the chip arrangement 100 is shown in FIG. 2, which represents a halfbridge circuit configuration. The ports 1, 2, 3, 4, 5 correspond to the pins C1 132, G1 136, E2 138, G2 140, and M-1 134, respectively.

According to the above exemplary embodiment wherein the first chip 102 and the second chip 112 are IGBT power semiconductor chips, the collector terminal 104 of the first chip 102 is electrically connected to the pin C1 132, i.e., port 1 of the circuit 200. The gate terminal 108 of the first chip 102 is electrically connected to the pin G1 136, i.e., port 2 of the circuit 200. The emitter terminal 116 of the second chip 112 is electrically connected to the pin E2 138, i.e., port 3 of the circuit 200. The gate terminal 118 of the second chip 112 is electrically connected to the pin G2 140. i.e., port 4 of the circuit 200. The emitter terminal 106 of the first chip 102, via its electrical connection to the second frame portion 126 through the bond wire 142, is electrically connected to the collector terminal 114 of the second chip 112. The collector terminal 114 of the second chip 112 is further electrically coupled to the pin M-1 134, which is port 5 of the circuit 200. In other words, the emitter terminal 106 of the first chip 102 and the collector terminal 114 of the second chip 112 are electrically connected at the pin M-1 134 (i.e. at port 5 of the circuit 200). The first IGBT chip 102 and the second IGBT chip 112 may each include a substrate diode as part of the IGBT chips 102, 112, and the substrate diodes are shown as part of the IGBT chips 102, 112 in the circuit 200 of FIG. 2.

An image illustrating the chip arrangement 100 of FIG. 1 is shown in FIG. 3.

In the above embodiment, the first chip 102 and the second chip 112 are IGBT power semiconductor chips. It is understood that the first chip 102 and the second chip 112 may be other types of power semiconductor chips, and the first chip 102 and the second chip 112 may be the same or different types of power semiconductor chips. For example, when the first chip 102 and the second chip 112 are power MOSFET or JFET chips, the contacts 104, 114 may be drain terminals, the contacts 106, 116 may be source terminals, and the contacts 108, 118 may be gate terminals of the first chip 102 and the second chip 112, respectively. In another example, wherein the first chip 102 and the second chip 112 are bipolar transistor power semiconductor chips, the contacts 104, 114 may be collector terminals, the contacts 106, 116 may be emitter terminals, and the contacts 108, 118 are may be terminals of the first chip 102 and the second chip 112, respectively.

In various embodiments, a gate driver may be provided on the second chip 112, e.g. for providing drive input for the first chip 102. In various embodiments, a gate driver may be mounted on but electrically isolated from the second leadframe portion 126, e.g. for providing drive input for the first chip 102 and/or the second chip 112.

According to an embodiment, additional Logic (e.g. a Gate driver) terminal may be coupled to a PWM (pulse width modulation)-Modulator, e.g. through one or more pins in additions to the five pins 132, 134, 136, 138, 140 above (e.g. through 4 additional pins), in which case the chip arrangement 100 may include 9 pins.

In the various embodiments, bond wires 142, 144, 146, 148 are used for the respective connection among the chips, the leadframe and the pins. Instead of bond wires, contact clips or contact ribbons or combinations thereof may be used for such connection in other embodiments.

The leadframe portions 124, 126 of the leadframe 122 may be made of a metal or a metal alloy, e.g. including a material selected from a group consisting of: copper (Cu), iron nickel (FeNi), steel and the like.

In various embodiments, the leadframe portions 124, 126 may be free from encapsulation material. In various embodiments, the leadframe portions 124, 126 may be partially free from encapsulation material. Furthermore, at least a portion of one or more of the pins 132, 134, 136, 138, 140 may be free of the encapsulation material. In various embodiments, at least a portion of the first pin 132 and at least a portion of the second pin 134 may be free of the encapsulation material.

The first leadframe portion 124 and the second leadframe portion 126 may be mechanically separated from each other, so as to be electrically insulated from each other. The distance L between the first leadframe portion 124 and the second leadframe portion 126 may be in the range from about 0.5 mm to about 50 mm, e.g., in the range from about 1 mm to about 10 mm in an embodiment. In an example, the distance L may be about 2.05 mm.

In various embodiments, a plurality of leadframe portions may be included in the chip arrangement 100 to form one common package. For example, a plurality of two half bridges or three half bridges (e.g., for motor control) may be formed in the chip arrangement, in which case only one gate driver may be used for all power transistors.

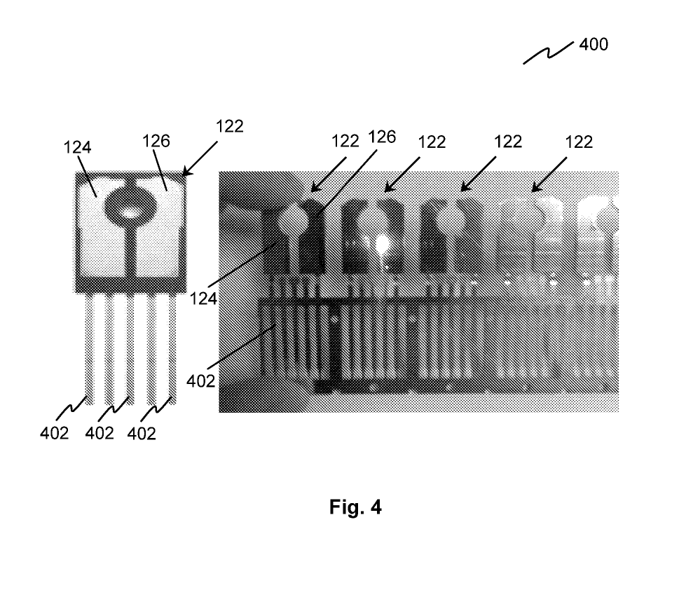

FIG. 4 shows a leadframe 400 according to various embodiments.

The leadframe 400 may include a plurality of leadframe units 122, wherein each leadframe unit 122 may be used in the chip arrangement 100 described in FIG. 1 above. Each leadframe unit 122 may include a first leadframe portion 124 and a second leadframe portion 126 electrically insulated from the first leadframe portion 124. A plurality of pins 402 may be (e.g. electrically conductively) coupled to the leadframe units 122. The pins 402 may be formed integrally with the leadframe portions 124, 126 as part of the leadframe units 122, or may be formed to be separate from the leadframe portions 124, 126.

In various embodiments, the plurality of leadframe units 122 are split from each other such that each leadframe unit 122 may be used for a single chip arrangement 100 above. In various embodiments, more than one leadframe units 122 may be used in a chip arrangement to integrate more chips in a single chip arrangement.

In the chip arrangement 100 described above, at least one leadframe portion of the plurality of leadframe portions 124, 126 may have a length in the range from about 1 mm to about 4 cm, e.g., in the range from about 1 mm to about 2 cm in various embodiments. At least one leadframe portion of the plurality of leadframe portions 124, 126 may have a width in the range from about 1 mm to about 2 cm, e.g. in the range from about 1 mm to about 1 cm in various embodiments.

In various embodiments, at least one pin of the plurality of pins 132, 134, 136, 138, 140 has a length in the range from about 1 mm to about 4 cm, e.g., in the range from about 1 mm to about 2 cm in various embodiments. In another embodiment, at least one pin of the plurality of pins 132, 134, 136, 138, 140 has a length in the range from about 0.5 cm to about 5 cm, e.g., in the range from about 1 cm to about 3 cm in an various embodiments.

In various embodiments, at least one pin of the plurality of pins 132, 134, 136, 138, 140 has a width in the range from about 0.5 mm to about 5 mm, e.g. in the range from about 1 mm to about 3 mm in various embodiments.

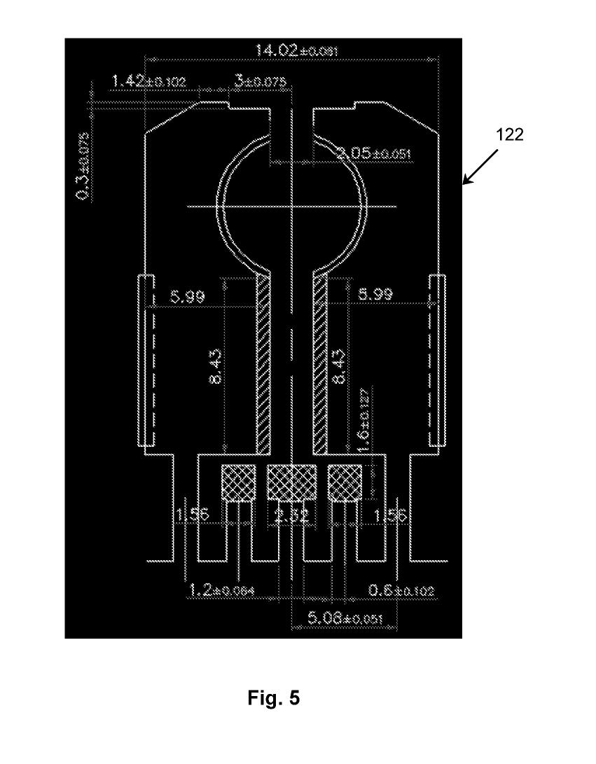

FIG. 5 shows a leadframe according to various embodiments, in which the exemplary dimensions of the leadframe 122 and the pins coupled to the leadframe 122 in the chip arrangement 100 of FIG. 1 (e.g. for a TO247-5 package) are illustrated.

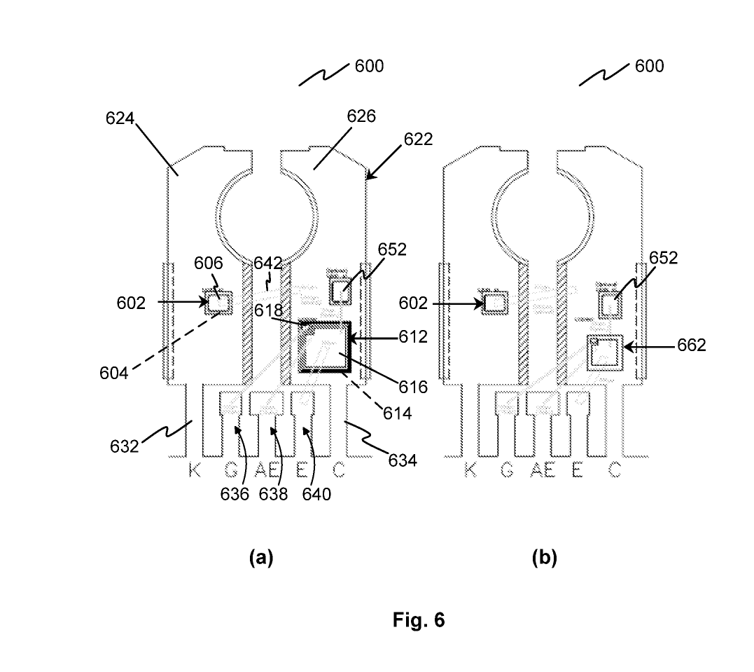

FIG. 6 shows a diagram illustrating a chip arrangement according to various embodiments.

Similar to the chip arrangement 100 of FIG. 1, the chip arrangement 600 includes a first chip 602, a second chip 612, and a leadframe 622 on which the first chip 602 and the second chip 612 are mounted. The leadframe 622 may include a first leadframe portion 624 and a second leadframe portion 626 electrically insulated from the first leadframe portion 624. In various embodiments, the first chip 602 may be mounted on the first leadframe portion 624, and the second chip 612 may be mounted on the second leadframe portion 626.

The first chip 602 may include a first contact 604 and a second contact 606. The first contact 604 may be positioned at the backside of the first chip 602, and may be electrically coupled to the first leadframe portion 624. The second contact 606 of the first chip 602 may be electrically coupled to the second leadframe portion 626, e.g. via one or more bond wires 642 connected between the second contact 606 and the second leadframe portion 626.

The second chip 612 may include a contact 614 electrically coupled to the second leadframe portion 626. The contact 614 may be positioned at the backside of the second chip 612.

The chip arrangement 600 may further include a plurality of pins 632, 634, 636, 638, 640 coupled to the leadframe 622. In various embodiments, at least one first pin 632 is coupled to the first leadframe portion 624, and at least one second pin 634 is coupled to the second leadframe portion 626. In various embodiments, as shown in FIG. 6, the first pin 632 and the second pin 634 may be formed as parts of the leadframe 622, for example, as pins extending from the first leadframe portion 1624 and the second leadframe portion 626. In various embodiments (not shown), the first pin 632 coupled to the first leadframe portion 624 and the second pin 634 coupled to the second leadframe portion 626 may also be formed to be separate from the leadframe portions 624, 626, and the electrical coupling therebetween may be formed via bonding wires, for example.

In various embodiments, as shown in FIG. 6, other pins 636, 638, 640 may be formed to be separate from the leadframe 622. These pins 636, 638, 640 may be configured to be electrically connected with the first chip 602 and the second chip 612, via bonding wires, for example. The first and second pins 632, 634 may have a first length, and the other pins 636, 638, 640 may have a second length smaller than the first length, as shown in various embodiments of FIG. 6.

At least one of the first chip 602 and the second chip 612 may include a power semiconductor chip.

In various embodiments of FIG. 6(a), the first chip 602 is a diode chip, and the second chip 612 is an IGBT chip.

The first contact 604 of the first chip 602 may be a Cathode terminal of the diode chip, which is coupled to the first leadframe portion 624 and to the first pin 632. The first pin 632 is depicted as K. The second contact 606 connected to the second leadframe portion 626 is an Anode terminal of the first chip 602.

The contact 614 of the second chip 612 may be a collector terminal of the IGBT chip 612. The collector contact 614 may be coupled to the second leadframe portion 626 and may further be coupled to the second pin 634 (depicted as C). The Anode terminal 606 of the first chip 602 may also be coupled to the second pin 634 through the bond wire 642 and the second leadframe portion 626. The second chip 612 may include an emitter terminal 616 coupled to the pin 638 (depicted as AE for emitter-sense) and the pin 640 (depicted as E for emitter) through bond wires. Further, a gate terminal 618 of the second chip 112 may be connected to the pin 636 (depicted as G) via one or more bond wires.

In various embodiments, the chip arrangement 600 may further include a third chip 652. The third chip 652 may be electrically (conductively) coupled to the second chip 612, for example, via bond wires. The third chip may be a diode chip, in various embodiments.

The chip arrangement 600 in FIG. 6(b) is similar to the chip arrangement 600 in FIG. 6(a), except that the second chip 662 is a MOSFET chip 662 and thus different from the second chip 612 of FIG. 6(a).

The chip arrangement 600 may be used as a power device for power factor control applications.

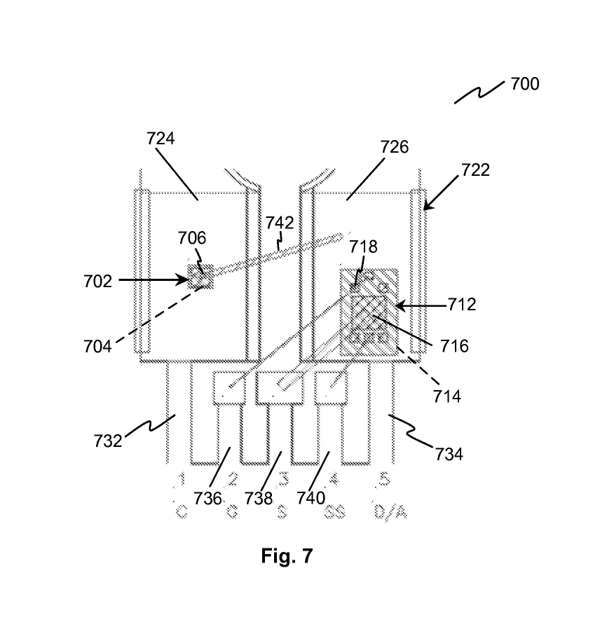

FIG. 7 shows a diagram illustrating a chip arrangement 700 according to various embodiments.

Similar to the chip arrangement 100, 600 of FIGS. 1 and 6 above, the chip arrangement 700 includes a first chip 702, a second chip 712, and a leadframe 722 on which the first chip 702 and the second chip 712 are mounted. The leadframe 722 may include a first leadframe portion 724 and a second leadframe portion 726 electrically insulated from the first leadframe portion 724.

The first chip 702 may include a first contact 704 and a second contact 706. The first contact 704 may be positioned at the backside of the first chip 702, and may be electrically coupled to the first leadframe portion 724. The second contact 706 of the first chip 702 may be electrically coupled to the second leadframe portion 726, e.g. via one or more bond wires 742 connected between the second contact 706 and the second leadframe portion 726.

The second chip 712 may include a contact 714 electrically coupled to the second leadframe portion 726. The contact 714 may be positioned at the backside of the second chip 712.

The chip arrangement 700 may further include a plurality of pins 732, 734, 736, 738, 740 coupled to the leadframe 722. In various embodiments, at least one first pin 732 is coupled to the first leadframe portion 724, and at least one second pin 734 is coupled to the second leadframe portion 726. The other pins 736, 738, 740 may be configured to be electrically connected with the first chip 702 and the second chip 712, via bonding wires, for example. The first and second pins 732, 734 may have a first length, and the other pins 736, 738, 740 may have a second length smaller than the first length.

At least one of the first chip 702 and the second chip 712 may include a power semiconductor chip.

In various embodiments, as shown in FIG. 7, the first chip 702 is a diode chip, and the second chip 712 is a CoolMOS™ chip.

The first contact 704 of the first chip 702 may be a Cathode terminal of the diode chip, which is coupled to the first leadframe portion 724 and to the first pin 732. The first pin 732 is depicted as C. The second contact 706 connected to the second leadframe portion 726 may be an Anode terminal of the first chip 702.

The contact 714 of the second chip 712 may be a drain terminal of the CoolMOS™ chip 712. The drain contact 714 is coupled to the second leadframe portion 726 and is further coupled to the second pin 734 (depicted as D/A for the drain terminal of the CoolMOS™ chip 712 and the Anode terminal of the diode chip 702). The Anode terminal 706 of the first chip 702 may be coupled to the second pin 734 through the bond wire 742 and the second leadframe portion 726. The second chip 712 includes a source terminal 716 coupled to the pin 738 (depicted as S), and a further contact connected to the pin 740 (depicted as SS for source-sense) for source sensing. Further, a gate terminal 718 of the second chip 712 is connected to the pin 736 (depicted as G) via one or more bond wires.

In various embodiments above, the electrical coupling or connection in the chip arrangement 600, 700 may be achieved through bond wires, contact clips, contact ribbons, or combinations thereof.

In various embodiments above, the chip arrangement 100, 600, 700 may include a plurality of leadframe portions to form a multi-chip package, e.g. a multi-chip through-hole-package. A plurality of power semiconductor chips may be integrated in the chip arrangement 100, 600, 700, in which other chips, such as a gate driver or a controller chip, may also be integrated.

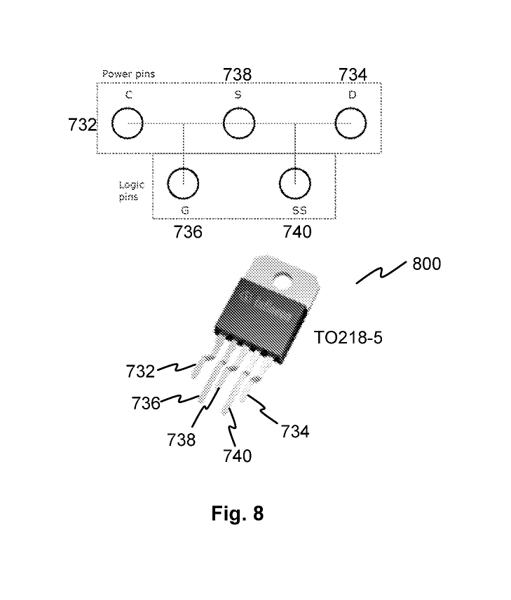

FIG. 8 shows a chip package 800 corresponding to the chip arrangement 700 of FIG. 7.

The chip arrangement 700 is encapsulated by encapsulation material to form the chip package 800, wherein at least a portion of one or more of the pins 732, 734, 736, 738, 740 is free of the encapsulation material. The chip package 800 may be formed as a through-hole package TO218-5.

According to various embodiments, at least one pin (e.g. the logic pins 736, 740) of the plurality of pins 732, 734, 736, 738, 740 is bent into a first direction, and at least one other pin(e.g. the power pins 732, 734, 738) of the plurality of pins 732, 734, 736, 738, 740 is bent into a second direction different from the first direction. In various embodiments, the second direction faces away from the first direction. The at least one pin (e.g. the logic pins 736, 740) of the plurality of pins bent into the first direction may be a control pin; and the at least one other pin (e.g. the power pins 732, 734, 738) of the plurality of pins bent into the second direction may be a power pin. In this manner, the logic pins may be arranged in one line and the power pins may be arranged in another line, which helps to decrease the required board space and reduce the assembly costs.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. A chip arrangement, comprising:
a first chip comprising a first contact and a second contact;
a second chip;
a leadframe comprising a first leadframe portion and a second leadframe portion electrically insulated from the first leadframe portion;
a plurality of pins coupled to the leadframe, wherein at least one first pin is coupled to the first leadframe portion and at least one second pin is coupled to the second leadframe portion;
wherein a shape of the first leadframe portion is mirror symmetric to a shape of the second leadframe portion:
wherein the first contact of the first chip is electrically coupled to the first leadframe portion and the second contact of the first chip is coupled to the second leadframe portion; and
wherein a contact of the second chip is electrically coupled to the second leadframe portion.

2. The chip arrangement of claim 1,
wherein at least one of the first chip and the second chip comprises a power semiconductor chip.

3. The chip arrangement of claim 1,
wherein at least one of the first chip and the second chip have a chip size in the range from about 1 mm² to about 800 mm².

4. The chip arrangement of claim 1,
wherein at least one leadframe portion of the plurality of leadframe portions has a length in the range from about 1 mm to about 4 cm.

5. The chip arrangement of claim 1,
wherein at least one leadframe portion of the plurality of leadframe portions has a width in the range from about 1 mm to about 2 cm.

6. The chip arrangement of claim 1,
wherein at least one pin of the plurality of pins has a length in the range from about 1 mm to about 4 cm.

7. The chip arrangement of claim 1,
wherein at least one pin of the plurality of pins has a length in the range from about 0.5 cm to about 5 cm.

8. The chip arrangement of claim 1,
wherein at least one pin of the plurality of pins has a width in the range from about 0.5 mm to about 5 mm.

9. The chip arrangement of claim 1,
wherein at least one pin of the plurality of pins has a first length and at least one other pin of the plurality of pins has a second length, wherein the second length is smaller than the first length.

10. The chip arrangement of claim 1,
wherein the leadframe portions are free from encapsulation material.

11. The chip arrangement of claim 1,
wherein the leadframe portions are made of a metal or a metal alloy.

12. The chip arrangement of claim 1,
wherein at least one pin of the plurality of pins is bent into a first direction; and
wherein at least one other pin of the plurality of pins is bent into a second direction;
wherein the second direction is different from the first direction.

13. The chip arrangement of claim 12,
wherein the second direction faces away from the first direction.

14. The chip arrangement of claim 12,
wherein the at least one pin of the plurality of pins bent into the first direction is a control pin; and
wherein the at least one other pin of the plurality of pins bent into the second direction is a power pin.

15. The chip arrangement of claim 1,
wherein the first chip comprises a field effect transistor power semiconductor chip; and
wherein the second contact of the first chip is a source contact of the field effect transistor power semiconductor chip.

16. The chip arrangement of claim 1,
wherein the first chip comprises a bipolar transistor power semiconductor chip; and
wherein the second contact of the first chip is an emitter contact of the bipolar transistor power semiconductor chip.

17. A chip package, comprising:
a chip arrangement, comprising:
a first chip comprising a first contact and a second contact;
a second chip;
a leadframe comprising a first leadframe portion and a second leadframe portion electrically insulated from the first leadframe portion;
a plurality of pins coupled to the leadframe, wherein at least one first pin is coupled to the first leadframe portion and at least one second pin is coupled to the second leadframe portion;
wherein a shape of the first leadframe portion is mirror symmetric to a shape of the second leadframe portion;
wherein the first contact of the first chip is electrically coupled to the first leadframe portion and the second contact of the first chip is coupled to the second leadframe portion; and
wherein a contact of the second chip is electrically coupled to the second leadframe portion;
encapsulation material encapsulating the chip arrangement, wherein at least a portion of the first pin and at least a portion of the second pin is free of the encapsulation material.

18. The chip package of claim 17,
wherein the chip package is configured as a through hole package.

19. The chip package of claim 17,
wherein the first chip comprises a field effect transistor power semiconductor chip; and
wherein the second contact of the first chip is a source contact of the field effect transistor power semiconductor chip.

20. The chip package of claim 17,
wherein the first chip comprises a bipolar transistor power semiconductor chip; and
wherein the second contact of the first chip is an emitter contact of the bipolar transistor power semiconductor chip.
